(19) United States
(12) Patent Application Publication
(10) Pub. No.: US 2008/0179085 A1
(43) Pub. Date: Jul. 31, 2008

(54) PRINTED CIRCUIT BOARD AND DISPLAY PANEL ASSEMBLY HAVING THE SAME

(75) Inventors: Kil-Soo CHOI, Suwon-si (KR); Sun-Hyung CHOI, Hwaseong-si (KR); Ji-Young KIM, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD, Suwon-si (KR)

(21) Appl. No.: 12/017,179

(22) Filed: Jan. 21, 2008

(30) Foreign Application Priority Data
Jan. 26, 2007 (KR) 10-2007-0008520

(51) Int. Cl. H05K 1/02

(52) U.S. Cl. 174/261

(57) ABSTRACT

A printed circuit board (“PCB”) includes a base substrate, circuit lines and an input pad portion. The input pad portion is formed on a surface of the base substrate on which the circuit lines are formed to receive an externally provided signal. The input pad portion includes a first input pad group, a second input pad group and a first connecting member. The first input pad group has a plurality of first input terminals. The second input pad group is spaced apart from the first input pad group. The second input pad group includes a plurality of second input terminals. At least one of the second input terminals is electrically connected to at least one of the first input terminals. The first connecting member electrically connects at least two of the second input terminals.

The present application claims priority to Korean Patent Application No. 2007-8520, filed on Jan. 26, 2007, and all the benefits accruing therefrom under 35U.S.C. §119, the contents of which in its entirety are herein incorporated by reference.

### BACKGROUND OF THE INVENTION

1. Field of the Invention

The present invention relates to a display panel assembly. More particularly, the present invention relates to a printed circuit board (“PCB”) and a display panel assembly having the PCB.

2. Description of the Related Art

A liquid crystal display (“LCD”) device as a type of flat panel display device displays an image using electrical and optical characteristics of liquid crystal.

The LCD device includes a liquid crystal control unit that controls a liquid crystal material and a light-providing unit that provides the liquid crystal with light. For example, the LCD device includes a display panel assembly serving as the liquid crystal control unit, and a backlight assembly serving as the light-providing unit.

The display panel assembly includes a printed circuit board (“PCB”) to drive a display panel. Circuit lines are typically formed on both sides or a single side of the PCB.

When the circuit lines are formed on the both sides of the PCB, a via hole is used to connect intersecting circuit lines formed on both sides of the PCB, thereby decreasing the number of input terminals receiving an externally provided signal. However, since the circuit lines are formed on both sides of the PCB, manufacturing costs are increased.

When the circuit lines are formed on only a single side of the PCB, manufacturing costs are reduced. However, since the circuit lines do not intersect each other, the circuit lines are limited in design. Therefore, the number of input terminals receiving an externally provided signal is increased.

### BRIEF SUMMARY OF THE INVENTION

The present invention obviates the above problems and thus, the present invention provides a printed circuit board (“PCB”) capable of decreasing the number of input terminals to reduce manufacturing costs.

The present invention also provides a display panel assembly having the above-mentioned PCB.

In an exemplary embodiment of the present invention, a PCB includes a base substrate, circuit lines and an input pad portion. The circuit lines are formed on a surface of the base substrate. The input pad portion is formed on the surface having the circuit lines of the base substrate to receive an externally provided signal. The input pad portion includes a first input pad group, a second input pad group and a first connecting member. The first input pad group has a plurality of first input terminals. The second input pad group is spaced apart from the first input pad group. The second input pad group includes a plurality of second input terminals. At least one of the second input terminals is electrically connected to at least one of the first input terminals. The first connecting member electrically connects at least two of the second input terminals. The at least one of the second input terminals being electrically connected to at least one of the first input terminals is via a circuit line of the circuit lines.

In an exemplary embodiment, the first connecting member may include at least one of an auxiliary PCB, a conductive tape and a surface mount gasket. Here, the auxiliary PCB, the conductive tape and the surface mount gasket are disposed on the second input terminals. The auxiliary PCB and the second input terminals may be electrically connected to each other by an anisotropic conductive film or a solder.

In an exemplary embodiment, the second input terminals receive a same signal, and the at least one of the first input terminals electrically connected to the second input terminals receives the same signal as the second input terminals. The second input terminals may be grounded or connected to a power supply.

The input pad portion may optionally include a third input pad group formed on the surface having the circuit lines of the base substrate and spaced apart from the first input pad group and the second input pad group. Here, the third input pad group includes a plurality of third input terminals. At least one of the third input terminals may be electrically connected to at least one of the first input terminals, and the third input terminals may be electrically insulated from the second input terminals.

The input pad portion may further include a second connecting member electrically connecting at least two of the third input terminals. For example, the second connecting member may include one of an auxiliary PCB, a conductive tape and a surface mount gasket. Here, the auxiliary PCB, the conductive tape and the surface mount gasket are disposed on the third input terminals. The auxiliary PCB and the third input terminals may be electrically connected to each other by an anisotropic conductive film or a solder.

In an exemplary embodiment, the third input terminals receive a same signal, and the at least one of the first input terminals electrically connected to the third input terminals receives the same signal as the third input terminals. The third input terminals may be grounded or connected to a power supply.

In an exemplary embodiment, the second input pad group and the third input pad group are spaced apart from the first input pad group by substantially a same distance to be located in a row.

In an exemplary embodiment, the third input terminals may be electrically connected to the second input terminals. The third input terminals, the at least one of the first input terminals and the second input terminals may receive a same signal.

In another exemplary embodiment of the present invention, a display panel assembly includes a display panel and a PCB. The display panel displays an image using light. The PCB includes a base substrate, circuit lines and an input pad portion. The circuit lines are formed on a surface of the base substrate. The input pad portion is formed on the surface having the circuit lines of the base substrate to receive an externally provided signal. The input pad portion includes a first input pad group, a second input pad group and a first connecting member. The first input pad group has a plurality of first input terminals. The second input pad group is spaced apart from the first input pad group. The second input pad group includes a plurality of second input terminals. At least one of the second input terminals is electrically connected to at least one of the first input terminals. The at least one of the second input terminals being electrically connected to at least one of the first input terminals is via a circuit line of the circuit lines. The first connecting member electrically connects at least two of the second input terminals.

In the above exemplary embodiments, a PCB has circuit lines on only a single side, and the number of input terminals receiving an externally provided signal may be decreased, thereby reducing manufacturing costs.

### BRIEF DESCRIPTION OF THE DRAWINGS

The above and other features and advantages of the present invention will become more apparent by describing in more detail exemplary embodiments thereof with reference to the accompanying drawings, in which:

FIG. 1 is a perspective partial view illustrating an exemplary embodiment of a display panel assembly according to the present invention;

FIG. 2 is a partial plan view illustrating an exemplary printed circuit board (“PCB”) illustrated in FIG. 1;

FIG. 3 is a partial cross-sectional view illustrating an exemplary embodiment of a PCB according to the present invention, which is taken along line I-I′ in FIG. 2;

FIG. 4 is a partial cross-sectional view illustrating the PCB of FIG. 3 taken along line II-II′ in FIG. 2;

FIG. 5 is a partial cross-sectional view illustrating another exemplary embodiment of a PCB according to the present invention, which is taken along line II-II′ in FIG. 2;

FIG. 6 is a partial cross-sectional view illustrating still another exemplary embodiment of a PCB according to the present invention, which is taken along line I-I′ in FIG. 2;

FIG. 7 is a partial cross-sectional view illustrating still another exemplary embodiment of a PCB according to the present invention, which is taken along line II-II′ in FIG. 2; and

FIG. 8 is a partial plan view illustrating yet another exemplary embodiment of a PCB according to the present invention.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “lower,” “under”,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “lower” other elements or features would then be oriented “above” the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in further detail with reference to the accompanying drawings.

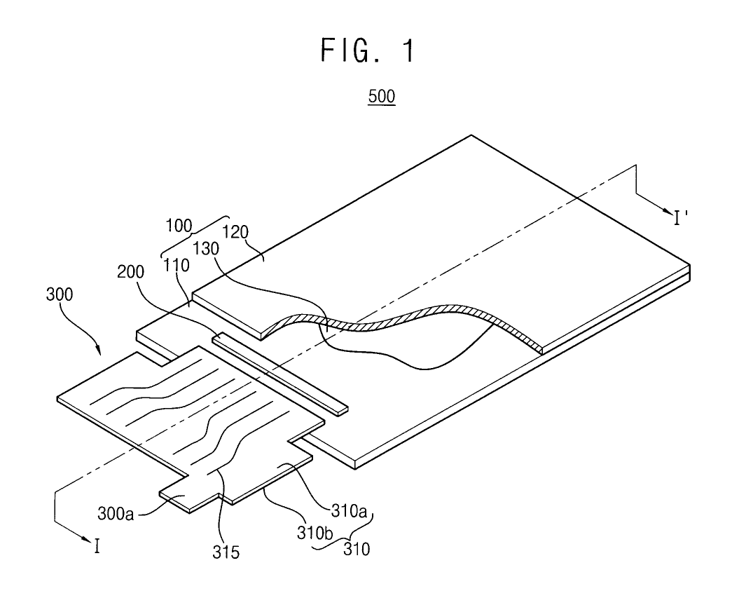

FIG. 1 is a perspective partial view illustrating an exemplary embodiment of a display panel assembly according to the present invention.

Referring to FIG. 1, a display panel assembly 500 includes a display panel 100, a driver chip 200 and a printed circuit board (“PCB”) 300. The display panel assembly 500 displays an image using externally provided light.

The display panel 100 includes a first substrate 110, a second substrate 120 and a liquid crystal layer 130 disposed therebetween.

For example, the first substrate 110 may include a plurality of pixel electrodes (not shown) arranged in a matrix shape, a plurality of thin-film transistors (“TFTs”) (not shown) which apply driving voltages to the pixel electrodes, a plurality of gate lines (not shown) and a plurality of data lines (not shown).

In an exemplary embodiment, the second substrate 120 may include a color filter (not shown) facing the pixel electrodes formed on the first substrate 110, and a common electrode (not shown) formed on the color filter.

The PCB 300 is electrically connected to a side portion of the display panel 100 to provide the display panel 100 with a driving signal to drive the display panel 100. For example, the PCB 300 may include a flexible PCB (“FPCB”) having flexibility in exemplary embodiments.

The driver chip 200 is disposed on the first substrate 110. The driver chip 200 controls timing to apply the driving signal provided from the PCB 300 to the display panel 100. For example, a chip-on-glass (“COG”) may be used as the driver chip 200, in which the driver chip 200 is mounted directly on the display panel 100.

The PCB 300 has an extension portion 300a extending from a predetermined location. An input pad portion that will be described later may be formed on the extension portion 300a.

Hereinafter, an input pad portion formed on the extension portion 300a will be described in further detail with reference to the accompanying drawings.

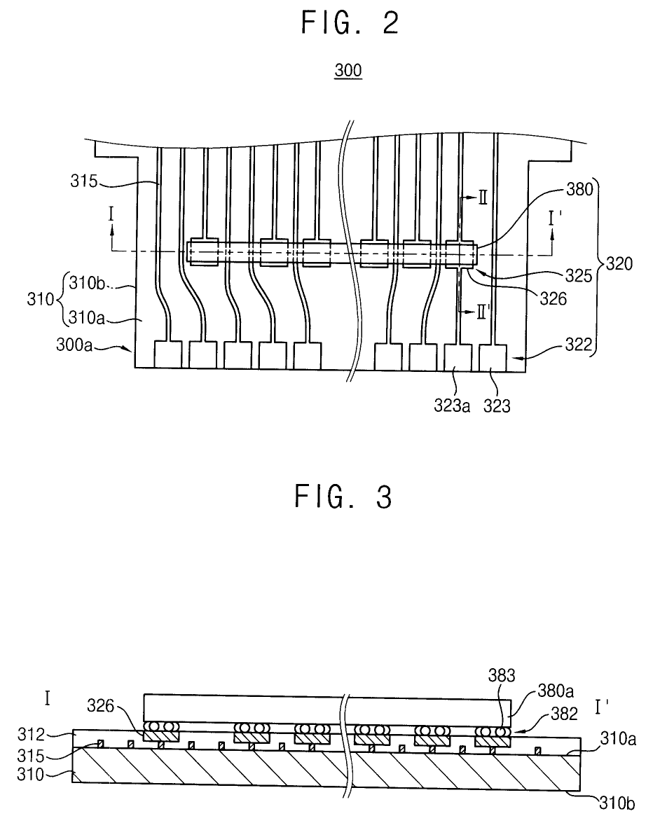

FIG. 2 is a partial plan view illustrating the exemplary PCB illustrated in FIG. 1.

Referring to FIGS. 1 and 2, the PCB 300 includes a base substrate 310, circuit lines 315 and an input pad portion 320.

The base substrate 310 includes a first surface 310a and a second surface 310b opposite the first surface 310a.

The circuit lines 315 are formed on the base substrate 310. In exemplary embodiments, the circuit lines 315 are formed on the first surface 310a of the base substrate 310 as illustrated in FIGS. 1 and 2.

The input pad portion 320 is formed on the base substrate 310 to receive an externally provided signal. In exemplary embodiments, the input pad portion 320 is formed on the first surface 310a of the base substrate 310 as illustrated in FIG. 2.

In an exemplary embodiment, the PCB 300 has the extension portion 300a that extends from a predetermined location and has a predetermined length. The input pad portion 320 may be formed on the extension portion 300a of the base substrate 310. As shown in FIG. 1, the extension portion 300a extends in a direction substantially parallel with a longitudinal direction of the display panel 100. Alternatively, the extension portion 300a may extend in any other direction.

In FIGS. 1 and 2, the input pad portion 320 is formed on the extension portion 300a. Alternatively, the input pad portion 320 may be formed on any other portion of the base substrate 310.

The input pad portion 320 includes a first input pad group 322, a second input pad group 325 and a connecting member 380.

The first input pad group 322 has a plurality of first input terminals 323. The first input terminals 323 receive an externally provided driving signal which drives the display panel 310. The first input terminals 323 may include, for example, a ground terminal (GND), a power supply terminal (VDD3), etc.

The second input pad group 325 has a plurality of second input terminals 326. The second input terminals 326 are spaced apart from the first input pad group 322 and electrically connected to at least one of the first input terminals 323.

The connecting member 380 may electrically connect the second input terminals 326 to each other. Thus, the second input terminals 326 and the at least one of the first input terminals 323 may be electrically connected to each other.

The second input terminals 326 and the at least one of the first input terminals 323 electrically connected to the second input terminals 326 receive the same signal that is provided from an exterior. The second input terminals 326 may include, for example, one of a ground terminal (GND) and a power supply terminal (VDD3), for example, but is not limited thereto.

In an exemplary embodiment, the first input pad group 322 includes a ground terminal 323a. The ground terminal 323a is electrically connected to the second input terminals 326 of the second input pad group 325 through the circuit lines 315, and the second input terminals 326 are electrically connected to each other through the connecting member 380. Thus, the second input terminals 326 may serve as a ground terminal.

As described above, in the terminals of the PCB 300, which receive the same signal that is provided from the exterior, some of the terminals are located at the first input pad group 322 and remaining terminals are located at the second input pad group 325 spaced apart from the first input pad group 322 by a predetermined distance. Thereby the number of input terminals of the input pad portion 320 and the number of input terminals directly receiving an external signal are less.

The first input pad group 322 and the second input pad group 325 may be formed on the first surface 310a or a second surface 310b of the base substrate 310. For example, in an exemplary embodiment, the first input pad group 322 and the second input pad group 325 are formed on the first surface 310a. The circuit lines 315 may be formed only on the first surface 310a of the base substrate 310.

Thus, since the circuit lines 315 of the PCB 300 are formed on only one of the first surface 310a and the second surface 310b, manufacturing costs of the PCB 300 may be reduced.

In FIG. 2, although the input pad portion 320 is formed on the extension portion 300a, the second input pad group 325 may not be disposed on the extension portion 300a of the PCB 300 while the first input pad group 322 of the input pad portion 320 is disposed on the extension portion 300a.

As described above, the circuit lines 315 formed on the PCB 300 are formed on only one of the first surface 310a and the second surface 310b of the base substrate 310, and terminals receiving the same signal are spatially divided into the first input pad group 322 and the second input pad group 325 so that the circuit lines 315 do not cross each other. Thus, while the PCB 300 is designed to have a single-sided PCB, the number of the input terminals of the input pad portion 320, which directly receive an external signal, may be decreased. Thus, the manufacturing costs of the PCB 300 may be reduced.

Hereinafter, various exemplary embodiments of the connecting member 380 will be described in further detail with reference to the accompanying drawings.

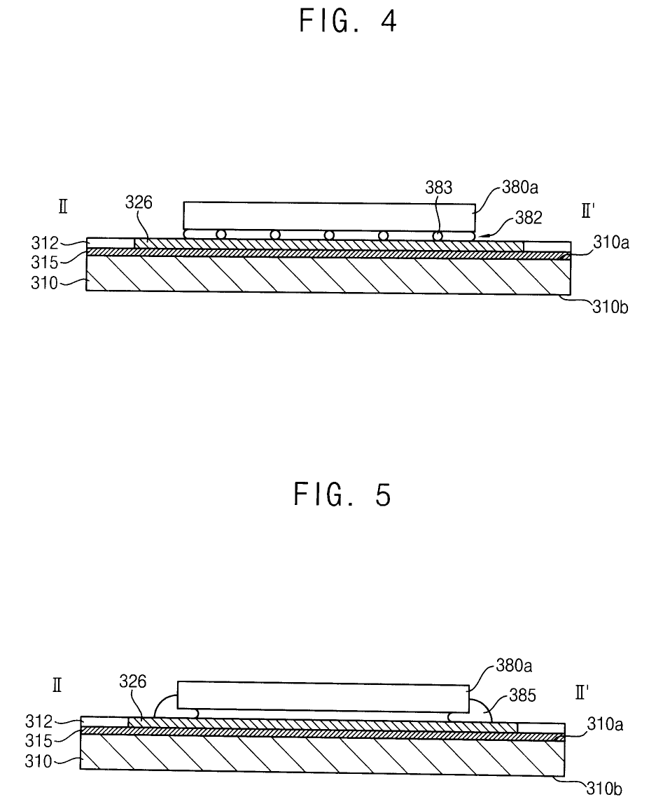

FIG. 3 is a partial cross-sectional view illustrating an exemplary embodiment of a PCB according to the present invention, which is taken along line I-I′ in FIG. 2. FIG. 4 is a partial cross-sectional view illustrating the PCB of FIG. 3 taken along line I′-I′ in FIG. 2.

Referring to FIGS. 3 and 4, the circuit lines 315 are formed on the first surface 310a of the base substrate 310 of the PCB 300. The circuit lines 315 are electrically connected to the second input terminals 326 formed on the circuit lines 315.

A coverlay 312 is formed on the base substrate 310 having the circuit lines 315. The coverlay 312 electrically insulates the circuit lines 315 from each other.

For example, the base substrate 310 may include polyimide, and the circuit lines 315 may include copper foil.

In FIGS. 3 and 4, the connecting member 380 shown in FIG. 2 corresponds to an auxiliary PCB 380a disposed on the second input terminals 326. The auxiliary PCB 380a electrically connects the second input terminals 326 to each other.

In FIGS. 3 and 4, an anisotropic conductive film (“ACF”) 382 is interposed between the auxiliary PCB 380a and the second input terminals 326. The anisotropic conductive film 382 includes a plurality of conductive balls 383. The auxiliary PCB 380a and the second input terminals 326 are coupled to each other through the anisotropic conductive film 382.

Accordingly, the auxiliary PCB 380a and the second input terminals 326 are physically and electrically connected to each other through the anisotropic conductive film 382, and thus the second input terminals 326 may be electrically connected to each other.

As shown in FIGS. 3 and 4, when the auxiliary PCB 380a is employed as the connecting member 380 in FIG. 2, the second input terminals 326 may be stably electrically connected to each other to secure excellent reliability.

FIG. 5 is a partial cross-sectional view illustrating another exemplary embodiment of a PCB according to the present invention, which is taken along line II-II′ in FIG. 2. The PCB illustrated in FIG. 5 is substantially the same as the PCB 300 illustrated in FIGS. 3 and 4 except for a connecting means between the auxiliary PCB 380a and the second input terminals 326. Thus, any further description will be omitted.

Referring to FIG. 5, the auxiliary PCB 380a and the second input terminals 326 are coupled to each other through a solder 385.

Thus, the auxiliary PCB 380a and the second input terminals 326 are physically and electrically connected to each other through the solder 385, and thus the second input terminals 326 may be electrically connected to each other.

When the auxiliary PCB 380a and the second input terminals 326 are coupled to each other through the solder 385 as shown in FIG. 5, a manufacturing process of the PCB 300 may be simplified and manufacturing costs of the PCB 300 may be reduced.

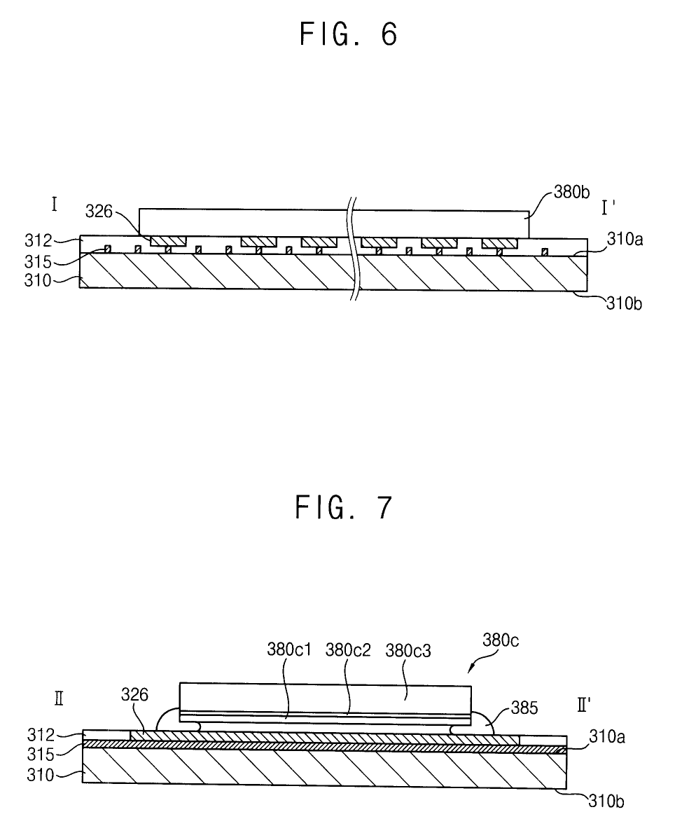

FIG. 6 is a partial cross-sectional view illustrating still another exemplary embodiment of a PCB according to the present invention, which is taken along line I-I′ in FIG. 2. The PCB illustrated in FIG. 6 is substantially the same as the PCB 300 illustrated in FIGS. 3 and 4 except for a connecting member 380 (FIG. 2). Thus, any further description will be omitted.

Referring to FIG. 6, the connecting member 380 shown in FIG. 2 corresponds to a conductive tape 380b disposed on the second input terminals 326. The conductive tape 380b electrically connects the second input terminals 326 to each other.

The conductive tape 380b is adhesive and has electrical conductivity. Therefore, the conductive tape 380b and the second input terminals 326 are adhered to each other due to the adhesiveness of the conductive tape 380b, and electrically connected to each other due to the electrical conductivity of the conductive tape 380b.

Accordingly, the conductive tape 380b and the second input terminals 326 are physically and electrically connected to each other, and thus the second input terminals 326 are electrically connected to each other.

As shown in FIG. 6, when the conductive tape 380b is employed as the connecting member 380 in FIG. 2, a manufacturing process of the PCB 300 may be simplified and manufacturing costs of the PCB 300 may be reduced.

FIG. 7 is a partial cross-sectional view illustrating still another exemplary embodiment of a PCB according to the present invention, which is taken along line II-II′ in FIG. 2. The PCB illustrated in FIG. 7 is substantially the same as the PCB 300 illustrated in FIGS. 3 and 4 except for a connecting member 380 (FIG. 2). Thus, any further description will be omitted.

Referring to FIG. 7, the connecting member 380 shown in FIG. 2 corresponds to a surface mount gasket 380c disposed on the second input terminals 326. The surface mount gasket 380c electrically connects the second input terminals 326 to each other.

The surface mount gasket 380c may include, for example, a solderable tin-plated copper shim 380c1, a conductive adhesive 380c2 and a gasket body 380c3. Thus, as shown in FIG. 7, the surface mount gasket 380c may be coupled to the second input terminals 326 through the solder 385, and electrically connected to each other due to electrical conductivity of the solder 385.

Accordingly, the surface mount gasket 380c and the second input terminals 326 are physically and electrically connected to each other through the solderable tin-plated copper shim 380c1, and thus the second input terminals 326 may be electrically connected to each other.

As shown in FIG. 7, when the surface mount gasket 380c is employed as the connecting member 380 in FIG. 2, the second input terminals 326 may be stably electrically connected to each other.

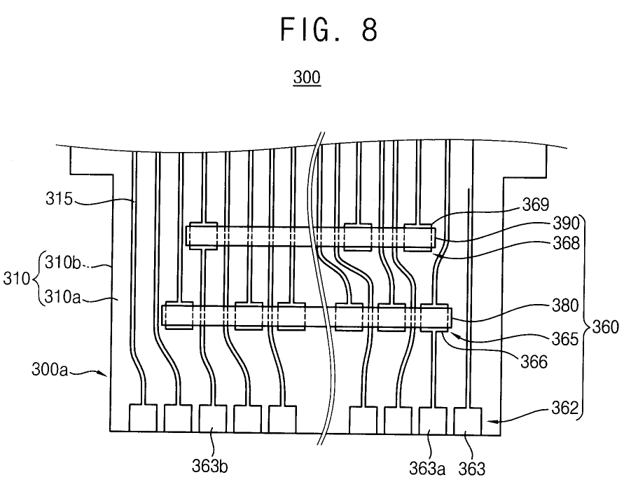

FIG. 8 is a partial plan view illustrating still yet another exemplary embodiment of a PCB according to the present invention. The PCB illustrated in FIG. 8 is substantially the same as the PCB 300 illustrated in FIG. 2 except for an input pad portion 320 (FIG. 2). Thus, any further description will be omitted.

Referring to FIGS. 1 and 8, the PCB 300 includes a base substrate 310, circuit lines 315 and an input pad portion 360.

The input pad portion 360 is formed on the base substrate 310 to receive an externally provided signal.

In an exemplary embodiment, the PCB 300 has the extension portion 300a extending from a predetermined location and having a predetermined length. The input pad portion 360 may be formed on the extension portion 300a of the base substrate 310. As shown in FIG. 1, the extension portion 300a extends in a direction substantially parallel with a longitudinal direction of the display panel 100. Alternatively, the extension portion 300a may extend in any other direction.

In FIGS. 1 and 8, the input pad portion 360 is formed on the extension portion 300a. Alternatively, the input pad portion 360 may be formed on any other portion of the base substrate 310.

The input pad portion 360 includes a first input pad group 362, a second input pad group 365 and a third input pad group 368.

The first input pad group 362 has a plurality of first input terminals 363. The first input terminals 363 receive an externally provided driving signal which drives the display panel 310. The first input terminals 363 may include, for example, a ground terminal (GND), a power supply terminal (VDD3), etc.

The second input pad group 365 has a plurality of second input terminals 366. The second input terminals 366 are spaced apart from the first input pad group 362 and electrically connected to at least one of the first input terminals 363.

The input pad portion 360 includes a first connecting member 380. The first connecting member 380 electrically connects the second input terminals 366 to each other. Thus, the second input terminals 366 and the at least one of the first input terminals 363 may be electrically connected to each other.

One of the connecting members 380a, 380b and 380c illustrated in FIGS. 3 to 7 may be employed as the first connecting member 380.

The second input terminals 366 and the at least one of the first input terminals 363 electrically connected to the second input terminals 366 receive the same signal that is provided from an exterior. The second input terminals 366 may include, for example, one of a ground terminal (GND) and a power supply terminal (VDD3), for example, but is not limited thereto.

The third input pad group 368 has a plurality of third input terminals 369. The third input terminals 369 are spaced apart from the first input pad group 362 and the second input pad group 365. The third input terminals 369 are electrically connected to at least one of the first input terminals 363. The third input terminals 369 may be electrically insulated from the second input terminals 366.

Although not shown in FIG. 8, in another exemplary embodiment, the third input terminals 369 of the third input pad group 368 may be electrically connected to the second input terminals 366 of the second input pad group 365. For example, when a large number of the terminals receiving the same signal are formed on the extension portion 300a, the second input terminals 366 and the third input terminals 369 may receive the same signal and be spaced apart from each other to obtain an advantageous configuration.

The input pad portion 360 may further include a second connecting member 390. The second connecting member 390 electrically connects the third input terminals 369 to each other. Thus, the third input terminals 369 and the at least one of the first input terminals 363 may be electrically connected to each other.

One of the connecting members 380a, 380b and 380c illustrated in FIGS. 3 to 7 may be employed as the second connecting member 390.

The third input terminals 369 and the at least one of the first input terminals 363 electrically connected to the third input terminals 369 receive the same signal that is provided from an exterior. The third input terminals 369 may include, for example, one of a ground terminal (GND) and a power supply terminal (VDD3), for example, but is not limited thereto. In an exemplary embodiment, the second input terminals 366 include a ground terminal (GND), and the third input terminals 369 include a power supply terminal (VDD3). Alternatively, the second input terminals 366 and the third input terminals 369 may include a ground terminal (GND). Alternatively, the second input terminals 366 and the third input terminals 369 may include a power supply terminal (VDD3).

In an exemplary embodiment, the first input pad group 362 includes a ground terminal 363a and a power supply terminal 363b. The ground terminal 363a is electrically connected to the second input terminals 366 of the second input pad group 365 through the circuit lines 315, and the second input terminals 366 are electrically connected to each other through the first connecting member 380. In addition, the power supply terminal 363b is electrically connected to the third input terminals 369 of the third input pad group 368 through the circuit lines 315, and the third input terminals 369 are electrically connected to each other through the second connecting member 390. Thus, the second input terminals 366 may serve as a ground terminal, and the third input terminals 366 may serve as a power supply terminal.

As described above, in the terminals of the PCB 300, which receive the same signal that is provided from an exterior, some of the terminals are located at the first input pad group 362 and remaining terminals are located at the second input pad group 365 spaced apart from the first input pad group 362 by a first predetermined distance and located at the third input pad group 368 spaced apart from the first input pad group 362 by a second predetermined distance. Thereby the number of input terminals of the input pad portion 360 and the number of the input terminals directly receiving an external signal may be decreased.

For example, when terminals of the PCB 300, which receive the same signal that is provided from the exterior, are classified into two groups, terminals receiving a first signal may be located at the second input pad group 365 and terminals receiving a second signal may be located at the third input pad group 368, thereby decreasing the number of input terminals of the input pad portion 360 and the number of the input terminals directly receiving an external signal.

In FIG. 8, although the PCB 300 includes the second input pad group 365 and the third input pad group 368, when terminals of the PCB 300, which receive the same signal that is provided from the exterior, are classified into three or more groups, the PCB 300 may further include an additional input pad group.

In FIG. 8, the third input pad group 368 is disposed so that the second input pad group 365 is located between the first input pad group 362 and the third input pad group 368. Alternatively, the third input pad group 368 may be disposed at a side of the second input pad group 365. For example, when the terminals of the PCB 300, which receive the same signal that is provided from the exterior, are classified into two groups and terminals receiving a first signal (for example, GND) and terminals receiving a second signal (for example, VDD3) are successively located (for example, GND, GND, GND, VDD3, VDD3,) the second input pad group 365 receiving the first signal and the third input pad group 368 receiving the second signal are spaced apart from the first input pad group 362 by substantially the same distance to be located in a row.

In FIG. 8, although the input pad portion 360 is formed on the extension portion 300a, at least one of the second input pad group 365 and the third input pad group 368 may not be disposed on the extension portion 300a while the first input pad group 362 of the input pad portion 360 are disposed on the extension portion 300a.

As described above, an exemplary embodiment of a PCB according to the present invention is employed in a display panel assembly to drive a display panel. Alternatively, the exemplary PCB according to the present invention may be employed in various other cases when a single-sided PCB is used instead of a double-sided PCB while preventing the number of input terminals of an input pad portion from increasing.

As in the illustrated exemplary embodiments according to the present invention, circuit lines of a PCB are formed on one side of a base substrate, and terminals receiving the same signal are spatially divided into a plurality of input pad groups so that the circuit lines do not cross each other.

Advantageously, while the PCB may be designed to have a single-sided PCB, the number of input terminals of an input pad portion, which directly receive an external signal, may be decreased.

Therefore, manufacturing costs of the PCB may be reduced, and manufacturing costs of a display panel having the PCB may also be reduced.

Although exemplary embodiments of the present invention have been described, it is understood that the present invention should not be limited to these exemplary embodiments but various changes and modifications can be made by one of ordinary skill in the art within the spirit and scope of the present invention as hereinafter claimed.

What is claimed is:

1. A printed circuit board (PCB) comprising:
a base substrate;
circuit lines formed on a surface of the base substrate; and
an input pad portion formed on the surface having the circuit lines of the base substrate to receive an externally provided signal, the input pad portion comprising:
a first input pad group having a plurality of first input terminals;
a second input pad group spaced apart from the first input pad group, the second input pad group comprising a plurality of second input terminals, at least one of the second input terminals being electrically connected to at least one of the first input terminals; and
a first connecting member electrically connecting at least two of the second input terminals.

2. The printed circuit board of claim 1, wherein the first connecting member comprises at least one of an auxiliary printed circuit board, a conductive tape and a surface mount gasket, and the auxiliary printed circuit board, the conductive tape and the surface mount gasket are disposed on the second input terminals.

3. The printed circuit board of claim 2, wherein the auxiliary printed circuit board and the second input terminals are electrically connected to each other by an anisotropic conductive film or a solder.

4. The printed circuit board of claim 1, wherein the second input terminals receive a same signal, and the at least one of the first input terminals electrically connected to the second input terminals receives the same signal as the second input terminals.

5. The printed circuit board of claim 1, wherein the input pad portion further comprises a third input pad group formed on the surface having the circuit lines of the base substrate and spaced apart from the first input pad group, the third input pad group comprising a plurality of third input terminals, at least one of the third input terminals being electrically connected to at least one of the first input terminals.

6. The printed circuit board of claim 5, wherein the third input terminals are electrically insulated from the second input terminals.

7. The printed circuit board of claim 5, wherein the input pad portion further comprises a second connecting member electrically connecting at least two of the third input terminals.

8. The printed circuit board of claim 5, wherein the third input terminals receive a same signal, and the at least one of the first input terminals electrically connected to the third input terminals receives the same signal as the third input terminals.

9. The printed circuit board of claim 5, wherein the second input pad group and the third input pad group are spaced apart from the first input pad group by substantially a same distance to be located in a row.

10. The printed circuit board of claim 5, wherein the third input terminals are electrically connected to the second input terminals, and
the third input terminals, the at least one of the first input terminals and the second input terminals receive a same signal.

11. A display panel assembly comprising:
a display panel configured to display an image using light; and
a printed circuit board electrically connected to a side portion of the display panel to provide the display panel with a driving signal, the printed circuit board comprising:
a base substrate;
circuit lines formed on a surface of the base substrate; and
an input pad portion formed on the surface having the circuit lines of the base substrate to receive an externally provided signal, the input pad portion comprising a first input pad group having a plurality of first input terminals, a second input pad group spaced apart from the first input pad group, and a first connecting member electrically connecting at least two of the second input terminals, the second input pad group comprising a plurality of second input terminals, at least one of the second input terminals being electrically connected to at least one of the first input terminals.

12. The display panel assembly of claim 11, wherein the first connecting member comprises one of an auxiliary printed circuit board, a conductive tape and a surface mount gasket, and the auxiliary printed circuit board, the conductive tape and the surface mount gasket are disposed on the second input terminals.

13. The display panel assembly of claim 12, wherein the auxiliary printed circuit board and the second input terminals are electrically connected to each other by one of an anisotropic conductive film and a solder.

14. The display panel assembly of claim 11, wherein the second input terminals receive a same signal, and the at least one of the first input terminals electrically connected to the second input terminals receives the same signal as the second input terminals.

15. The display panel assembly of claim 11, wherein the input pad portion further comprises a third input pad group formed on the surface having the circuit lines of the base substrate and spaced apart from the first input pad group, the third input pad group comprising a plurality of third input terminals, at least one of the third input terminals being electrically connected to at least one of the first input terminals.

16. The display panel assembly of claim 15, wherein the third input terminals are electrically insulated from the second input terminals.

17. The display panel assembly of claim 15, wherein the input pad portion further comprises a second connecting member electrically connecting at least two of the third input terminals with each other.

18. The display panel assembly of claim 15, wherein the third input terminals receive a same signal, and the at least one of the first input terminals electrically connected to the third input terminals receives the same signal as the third input terminals.

19. The display panel assembly of claim 15, wherein the second input pad group and the third input pad group are spaced apart from the first input pad group by substantially a same distance to be located in a row.

20. The display panel assembly of claim 15, wherein the third input terminals are electrically connected to the second input terminals, and
the third input terminals, the at least one of the first input terminals and the second input terminals receive a same signal.
